(19) United States
(12) Patent Application Publication
(10) Pub. No.: US 2010/0026284 A1
(43) Pub. Date: Feb. 4, 2010

(54) Element for Generating a Magnetic Field

(75) Inventors: Johannes Ante, Regensburg (DE); Markus Gilch, Mauern (DE); Stephan Heinrich, Pfeffenhausen (DE); Andreas Ott, Steinsberg (DE)

Correspondence Address: COHEN, PONTANI, LIEBERMAN & PAVANE LLP, 551 FIFTH AVENUE, SUITE 1210, NEW YORK, NY, 10176, US

(73) Assignee: Continental Automotive GmbH, Hannover (DE)

(21) Appl. No.: 12/442,252

(22) PCT Filed: Sep. 21, 2007
(86) PCT No.: PCT/EP07/60010

§ 371 Date: Mar. 20, 2009

(30) Foreign Application Priority Data
Sep. 21, 2006 (DE) 10 2006 044 668.2

(51) Int. Cl. G01R 33/07; H01F 7/04

(52) U.S. Cl. 324/226; 335/219

(57) ABSTRACT

An element for generating a magnetic field, having an annular frame for receiving an annular magnet which rotates with a turboshaft. The magnet is mounted in the frame such that the frame stabilizes and guides the magnet mechanically. In order to specify an element for generating a magnetic field which reliably fixes and guides the magnet, the magnet is connected to the frame by at least one spot weld.

The invention relates to an element for generating a magnetic field, having an annular frame for receiving an annular magnet which rotates with a turboshaft, wherein the magnet is mounted in the frame in such a way that the frame stabilizes and guides the magnet mechanically.

Supercharging is a frequently used technical solution for increasing the power of an internal combustion engine. It refers to the precompression of the combustion air by means of an exhaust gas turbocharger or else by means of a compressor which is driven mechanically by the engine. An exhaust gas turbocharger is composed essentially of a compressor and a turbine which are connected to a common shaft and rotate at the same rotational speed. The turbine converts the energy of the exhaust gas, which is usually output uselessly through the exhaust pipe, into rotational energy and drives the compressor. The compressor sucks in fresh air and feeds the precompressed air to the individual cylinders of the engine. An increased fuel quantity can be fed to the larger air quantity in the cylinders, as a result of which the internal combustion engine outputs more power. The combustion process is also favorably influenced, with the result that the internal combustion engine achieves a better overall efficiency level. Furthermore, the torque profile of an internal combustion engine which is supercharged with a turbocharger can be made extremely favorable.

In internal combustion engines having a large operating rotational speed range, for example in internal combustion engines for passenger cars, a high supercharging pressure is required at even low engine speeds. For this purpose, a supercharging control valve, referred to as a waste gate valve, is introduced into these turbochargers.

Selecting a corresponding turbine housing allows a high super-charging pressure to be built up quickly even at low engine speeds. When the engine speed rises, the waste gate valve then limits the supercharging pressure to a constant value.

As the exhaust gas quantity increases, the maximum permissible rotational speed of the combination of the turbine wheel, the compressor wheel and the turboshaft, which are also referred to as the rotating parts of the exhaust gas turbocharger, may be exceeded. If the rotational speed of the rotating parts is unacceptably exceeded, the rotating parts would be destroyed, which amounts to a total write-off of the turbocharger. Particularly modern and small turbochargers with significantly smaller turbine wheel diameters and compressor wheel diameters, which have an improved rotational acceleration behavior due to a considerably smaller moment of mass inertia, are affected by the problem of the acceptable maximum rotational speed being exceeded. Depending on the design of the turbocharger, the turbocharger is destroyed completely even if the rotational speed limit is exceeded by only approximately 5%.

Waste gate valves, which are actuated, for example, by a signal which results from the generated supercharging pressure, have proven suitable for limiting rotational speeds. If the super-charging pressure exceeds a predefined threshold value, the waste gate valve opens and conducts part of the exhaust gas mass flow past the turbine. The turbine takes up less power owing to the reduced mass flow and the compressor power decreases to the same degree. The supercharging pressure and the rotational speed of the turbine wheel and of the compressor wheel are reduced. However, this control is relatively slow acting since the build up of pressure when the rotational speed of the rotating parts is exceeded takes place after a time delay. For this reason, the rotational speed control for the turbocharger with monitoring of the supercharging pressure in the highly dynamic range (load change) has to intervene by reducing the supercharging pressure at a correspondingly early time, which leads to a loss of efficiency.

The German patent application with the application file number 10 2004 052 695.8, which was not published before the priority date of the present document, discloses an exhaust gas turbo-charger with a sensor at the compressor-side end of the turbo-shaft for directly measuring the rotational speed of the turbo-shaft. The sensor is guided here by the compressor housing and directed at an element for varying a magnetic field. The element for varying the magnetic field is embodied here as a permanent magnet. However, a permanent magnet is difficult to attach to the turboshaft since the latter rotates with a very high rotational speed and any unbalance has disadvantageous effects.

It is known to bond the permanent magnet into a frame in order to prevent magnetic material from becoming detached from the magnet. This has the disadvantage that the bonding agent outgasses and takes a very long time to harden completely. JP 10-206447 discloses an element for generating a magnetic field, having an annular frame for receiving an annular magnet which rotates with a turbine shaft.

The object of the present invention is therefore to specify an element for generating a magnetic field, having an annular frame for receiving an annular magnet which rotates with a turbine shaft and which securely fixes and guides the magnet and at the same time is cost-effective and inexpensive to manufacture.

This object is achieved according to the invention by means of the features of the independent claim 1.

Since the annular magnet is connected to the annular frame by means of at least one spot weld, a connection is possible between the frame and the magnet which is very cost-effective and can be produced quickly. Contrary to the prevailing opinion among specialists in the field that it is impossible to spot weld magnetic material, it became apparent when connecting the annular magnet to the annular frame that the magnet can be permanently fixed in position in the frame by spot welding. This is due to the fact that the connection between the magnet and the frame is not loaded in tension, compression or torsion, but the positions of the spot welds effectively prevent the magnet from rotating in the frame. This fixing of the magnets in position in the frame allows the use of bonding agents to be dispensed with completely. As a result, the bonding agent no longer outgasses and the connection between the magnet and the frame can be produced very quickly because there is no need for curing time which would be necessary if bonding agent were used.

In one development, the spot weld is embodied as a laser weld. Laser welding is a modern and efficient welding method in which the weld spot can be generated with high precision.

In another further development, the frame is embodied as a metal frame. A metal frame can be embodied with very thin walls and is nevertheless capable of receiving large forces which occur when the magnet rotates quickly about the axis of the turboshaft.

If the frame is embodied as an element for attaching the compressor wheel to the turboshaft, it fulfills a double function, which is particularly economic.

In one refinement, the frame is embodied as a cap nut. The frame therefore advantageously directs the airstream in the air inlet of the compressor to the compressor wheel. The formation of eddies in the airstream is avoided, which has a positive effect on the efficiency level of the turbocharger.

In another refinement, the magnet contains at least one metal from the group of rare earths, it being particularly advantageous if the magnet contains the metals iron and neodymium. It has become apparent that iron-neodymium magnets can be connected particularly satisfactorily to the frame by a spot weld.

Embodiments of the invention are illustrated by way of example in the figures, in which:

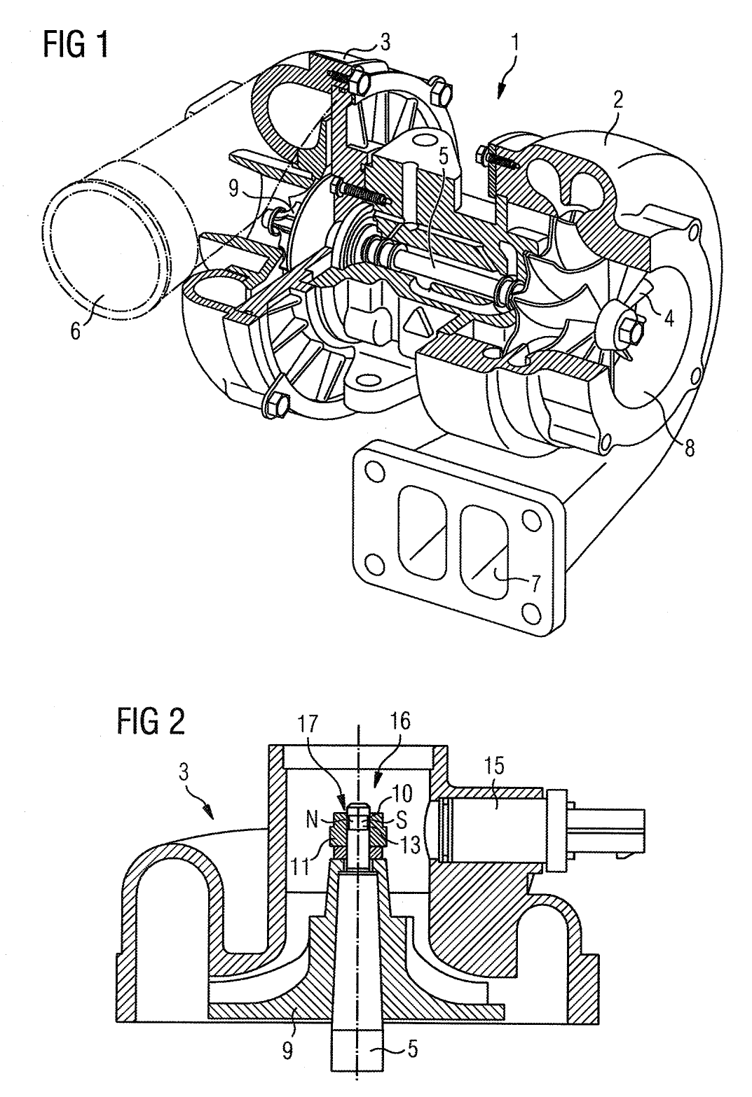

FIG. 1 shows an exhaust gas turbocharger with a turbine and a compressor,

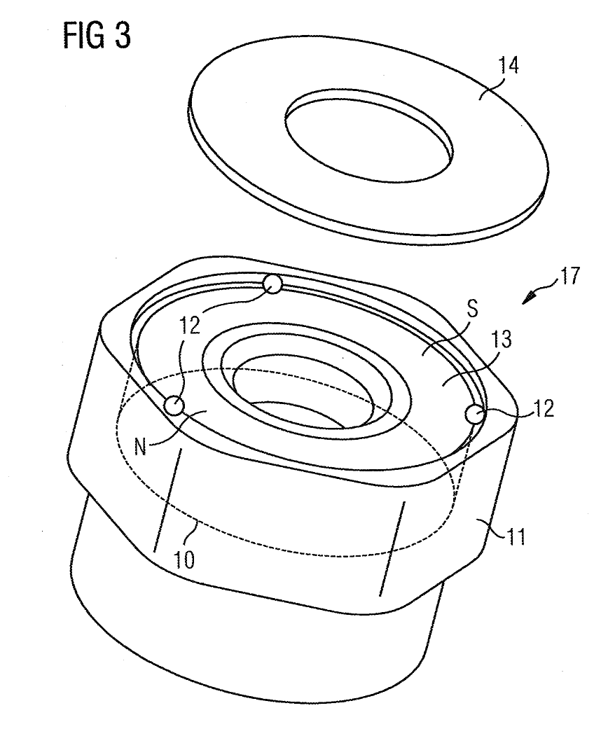

FIG. 2 shows the compressor in a sectional view, and

FIG. 3 shows the element for generating the magnetic field.

FIG. 1 shows an exhaust gas turbocharger 1 with a turbine 2 and a compressor 3. In the compressor 3, the compressor wheel 9 is rotatably mounted and connected to the turboshaft 5. The turboshaft 5 is also rotatably mounted and connected at its other end to the turbine wheel 4. The combination of the compressor wheel 9, turboshaft 5 and turbine wheel 4 is also referred to as the rotating parts. Hot exhaust gas from an internal combustion engine (not illustrated here) is input into the turbine 2 via the turbine inlet 7, causing the turbine wheel 4 to rotate. The exhaust gas stream leaves the turbine 2 through the turbine outlet 8. The turbine wheel 4 is connected to the compressor wheel 9 via the turboshaft 5. The turbine 2 therefore drives the compressor 3. Air is sucked into the compressor 3 through the air inlet 16 and is then compressed in the compressor 3 and fed to the internal combustion engine via the air outlet 6.

FIG. 2 shows the compressor 3 in a sectional view. The compressor wheel 9 can be seen in the compressor housing 21. The compressor wheel 9 is mounted on the turboshaft 5 with the mounting element 11. The mounting element 11 can, for example, be a cap nut which is screwed onto a thread which is applied to the turboshaft 5, in order to clamp the compressor wheel 9 securely to the turboshaft 5, against a collar of said turboshaft 5. Between the mounting element 11 and the compressor wheel 9 there is an element 17 for generating a magnetic field. The element 17 for generating the magnetic field is composed here of a permanent magnet 13 and a frame 14. The magnet 13 has a north pole N and a south pole S. As the turboshaft 5 rotates, the element 17 for generating the magnetic field rotates along with it about the rotational axis of the turboshaft 5. In this context, the element 17 for generating the magnetic field generates a change in the magnetic field strength or in the magnetic field gradient in the sensor 15. This change in the magnetic field or in the field gradient generates, in the sensor 15, a signal which can be processed electronically and which is proportional to the rotational speed of the turboshaft 5. The sensor 15 for sensing the change in the magnetic field or in the field gradient may contain, for example, a Hall element, a magnetoresistive element or a coil.

FIG. 3 shows the element 17 for generating the magnetic field with the frame 10 and the magnet 13. The frame 10 is embodied here as a mounting element 11. The magnet 13 is arranged in the frame 10. The magnet 13 is embodied as a permanent magnet. The magnet 13 is fitted into the frame 10 and connected to the frame 10 using spot welds 12. The spot welds 12 fix the position of the magnet 13 in the frame 10. The frame 10 rotates with the magnet 13 about the axis of the turboshaft 5 at a very high rotational speed. Since the magnet 13 is generally fabricated from very brittle material, a small weakness in the material in the magnet 13 can lead to fracturing of the magnetic material. The frame 10 prevents fragments of the magnet 13 from getting into the air inlet 16 of the compressor 3. As a result of the spot welding 12, the magnet 13 can be connected to the frame 10 very quickly and at low cost.

Bonding the magnet 13 to the frame 10, as is known from the prior art, has considerable disadvantages since the bonding agents take a very long time to cure and also outgas over a very long time period. The use of spot welds 12 for connecting the magnet 13 to the frame 10 simplifies and speeds up the manufacture of the frame significantly, giving rise to significant cost savings. Furthermore, spot welds 12 do not change their properties within the course of the operation of the frame within a turbocharger 1. On the other hand, bonded connections age over time, which, for example, can lead to the magnet 13 no longer being securely fixed in position in the frame 10. Furthermore, the connecting process of spot welding does not require additional materials, which has a very advantageous effect on the execution of the connecting process.

FIG. 3 also shows a protective cap 14, which can also be in a hat shape, and with which the magnet 13 is protected against aggressive media in the air inlet 16 of the compressor 3. The protective cap 14 is, for this purpose, connected to the frame 10 by, for example, welding it onto the frame 10.

Careful note is also to be taken of the fact that experts in the field have assumed that welding, in particular spot welding, of magnetic material to other metal materials is not possible or produces extremely unstable results. Contrary to this view which is generally held in the specialist field, it has become apparent that the permanent magnet 13 can be fixed in a frame 10, as illustrated in FIG. 3, very satisfactorily with sufficient strength and durability by producing spot welds 12 using, for example, a laser welding method. These spot welds 12 in fact effectively prevent the magnet 13 from rotating relative to the frame 10, but do not take up any other loads. On the other hand, bonding points can lose their bonding properties in the course of time if the bonding agent ages chemically. The magnet 13 can then no longer be securely fixed in position in the frame 10 and it can rotate relative to the frame 10, as a result of which it is no longer possible to measure the rotational speed of the turboshaft 5 reliably. On the other hand, the fusing of the metal of the frame 10 with that of the magnet 13 occurs on a permanent basis and therefore ensures the functional capability of the element 17 to generate a magnetic field over its entire service life.

1.-7. (canceled)

8. An element for generating a magnetic field, comprising:
an annular magnet; and
an annular frame configured to receive, stabilize, and guide the annular magnet, the annular frame further configured to rotate with a turboshaft, of a turbo charger
wherein the annular magnet is connected to the annular frame by at least one spot weld.

9. The element for generating a magnetic field according to claim 8, wherein the spot weld is a laser weld.

10. The element for generating a magnetic field according to claim 8, wherein the annular frame is a metal frame.

11. The element for generating a magnetic field according to claim 8, wherein the annular frame is configured to attach a compressor wheel of a turbocharger to the turboshaft.

12. The element for generating a magnetic field according to claim 8, wherein the annular frame is a cap nut.

13. The element for generating a magnetic field according to claim 8, wherein the annular magnet contains at least one metal from the group of rare earth elements.

14. The element for generating a magnetic field according to claim 8, wherein the annular magnet contains iron and neodymium.

15. The element for generating a magnetic field according to claim 10, further comprising a cap configured to attach to the annular frame.

16. The element for generating a magnetic field according to claim 15, wherein the cap is welded to the annular frame.

17. The element for generating a magnetic field according to claim 8, further comprising a sensor configured to sense a change in a magnetic field strength generated by the annular magnet.

18. The element for generating a magnetic field according to claim 17, wherein the sensor is at least one of a magnetoresistive element, a Hall element, and a coil.

19. The element for generating a magnetic field according to claim 18, wherein an output of the sensor is proportional to an output speed of the turboshaft.

20. The element for generating a magnetic field according to claim 8, further comprising a sensor configured to sense a change in a magnetic field gradient generated by the annular magnet.

21. The element for generating a magnetic field according to claim 20, wherein the sensor is at least one of a magnetoresistive element, a Hall element, and a coil.

22. The element for generating a magnetic field according to claim 21, wherein an output of the sensor is proportional to an output speed of the turboshaft.
